(19) United States
(12) Patent Application Publication
(10) Pub. No.: US 2026/0239804 A1
(43) Pub. Date: Aug. 13, 2026

(54) SEMICONDUCTOR LIGHT-EMITTING DEVICE

(71) Applicant: HAMAMATSU PHOTONICS K.K., Hamamatsu-shi (JP)

(72) Inventors: Akio ITO, Shizuoka (JP); Yutaka TAKAGI, Shizuoka (JP); Masahiro HITAKA, Shizuoka (JP); Yoshitaka KUROSAKA, Shizuoka (JP); Tadataka EDAMURA, Shizuoka (JP)

(73) Assignee: HAMAMATSU PHOTONICS K.K., Hamamatsu-shi (JP)

(21) Appl. No.: 19/532,979

(22) Filed: Feb. 6, 2026

(30) Foreign Application Priority Data
Feb. 12, 2025 (JP) 2025-020638
Sep. 3, 2025 (JP) 2025-146302

(51) Int. Cl. H10H 29/85; H10H 29/855

(52) U.S. Cl. CPC H10H 29/857; H10H 29/855

(57) ABSTRACT

A semiconductor light-emitting device includes a plurality of unit light-emitting elements on a substrate, each unit light-emitting element has a laminated structure including an active layer, a photonic crystal layer, and a first contact layer and a second contact layers sandwiching the active layer and the photonic crystal layer, and the first contact layer of one unit light-emitting element and a second contact layer of another unit light-emitting element adjacent to the one unit light-emitting element are electrically connected by an electrode layer, whereby a plurality of light-emitting element arrays, each having a plurality of unit light-emitting elements arrayed in a row, are configured.

### TECHNICAL FIELD

The present disclosure relates to a semiconductor light-emitting device.

### BACKGROUND

Technologies related to this type of field include, for example, semiconductor light-emitting elements described in “M. Yoshida et al, “High-brightness Scalable Continuous-wave Single-mode Photonic crystal Laser.” Nature 618:727-732 (2023).” The semiconductor light-emitting element described in the above-described literature is a light-emitting element referred to as a so-called photonic crystal surface emitting laser (PCSEL). The semiconductor light-emitting element is configured by laminating a photonic crystal layer including an active layer and a phase modulation layer on a substrate.

### SUMMARY

The semiconductor light-emitting elements described above face the challenge of achieving higher output power from the perspective of expanding their applications. One approach to increasing the output power of semiconductor light-emitting elements is, for example, to increase the element area. However, due to an influence of the warping of the substrate caused by the heat generated during driving or the like, it is considered that there is a limit to increasing the output power of a semiconductor light-emitting element by increasing the element area. Moreover, simply increasing the size of the light-emitting region in accordance with the size of the element may cause problems such as mode competition and distortion of the beam pattern due to non-uniformity in the temperature distribution within the light-emitting region.

A method for suppressing mode competition and distortion of the beam pattern while increasing the element area is to form a light-emitting region array of the element. For example, the semiconductor light-emitting elements in Japanese Unexamined Patent Publication No. 2023-131320 are light-emitting elements called integrable Phase Modulating Surface Emitting Lasers (iPMSELs), which can output a two-dimensional beam pattern. In this semiconductor light-emitting element, a plurality of light-emitting regions separated from each other are arrayed on a single substrate. Mode competition and distortion of the beam pattern can be suppressed when such an array of the plurality of light-emitting regions is considered. However, warpage of the substrate due to heat generated during driving can still remain an issue.

Another approach to increasing the output power of semiconductor light-emitting devices is to array a plurality of semiconductor light-emitting devices. When such an array of a plurality of semiconductor light-emitting elements is considered, it is possible to array elements of a size that can eliminate a problem such as mode competition. In forming such arrays, when actually forming semiconductor light-emitting elements on a substrate, it is necessary to ensure uniform heat distribution and heat dissipation in order to guarantee the uniformity of light emission from each semiconductor light-emitting element.

The present disclosure has been made to solve the above problems, and an objective thereof is to provide a semiconductor light-emitting device capable of outputting high-output-power and uniform laser light.

The subject matter of the present disclosure is shown as follows.
[1] A semiconductor light-emitting device including a plurality of unit light-emitting elements on a substrate, wherein the unit light-emitting element has a laminated structure including an active layer and a photonic crystal layer, and first and second contact layers sandwiching the active layer and the photonic crystal layer, and wherein a first contact layer of one unit light-emitting element and a second contact layer of another unit light-emitting element adjacent to the one unit light-emitting element are electrically connected by an electrode layer, whereby a plurality of light-emitting element arrays, each having a plurality of unit light-emitting elements arrayed in a row, are configured.

In this semiconductor light-emitting device, the first contact layer of one unit light-emitting element is electrically connected to the second contact layer of the adjacent unit light-emitting element by the electrode layer, such that the plurality of light-emitting element arrays in which the plurality of unit light-emitting elements are arrayed in the array are configured. According to this configuration, it is possible to ensure a sufficient element size for each unit light-emitting element and reduce the influence of a Fabry-Perot resonance mode between end surfaces of the element. By providing a plurality of arrays of such light-emitting elements on the substrate, high-output-power and uniform laser light can be extracted.
[2] The semiconductor light-emitting device according to [1], wherein the plurality of light-emitting element arrays are electrically connected in parallel to each other. In this case, by electrically connecting a plurality of light-emitting element arrays in parallel, it is possible to extract laser light from each unit light-emitting element while eliminating an influence of warping of the substrate due to heat generated during driving and a problem such as mode competition. Thereby, it is possible to extract the laser light with desired characteristics at high output power. Moreover, replacement of light-emitting element arrays and mounting of fuse elements can be easily implemented.
[3] The semiconductor light-emitting device according to [1] or [2], wherein the unit light-emitting elements are linearly arrayed in the light-emitting element array. In this case, the light-emitting element array can be efficiently arranged on the substrate. Moreover, the electrical connection between light-emitting element arrays can be implemented at the array end portion of the light-emitting element arrays. Thereby, because the region of the substrate where the unit light-emitting elements are located can be clearly separated from the region where the light-emitting element arrays are connected to each other, it is possible to uniformly control the temperature of the region where the unit light-emitting elements are located, thereby implementing a more uniform laser light output.
[4] The semiconductor light-emitting device according to [1] or [2], wherein the unit light-emitting elements are arrayed to have one or more bends in the light-emitting element array. In this case, the light-emitting element array can be efficiently arranged on the substrate. Moreover, the electrical connection between the light-emitting element arrays can be implemented at the array end portion of the light-emitting element arrays. Because the region where the unit light-emitting elements are located can be clearly separated from the region where the light-emitting elements are connected to each other, the region where the unit light-emitting elements are located can be uniformly controlled in temperature, enabling a more uniform laser light output.
[5] The semiconductor light-emitting device according to any one of [1] to [4], wherein, in one of the unit light-emitting elements, the first contact layer forms an outermost layer on the substrate side in the laminated structure and has a projecting portion projecting toward the unit light-emitting element of a connection destination from the laminated structure in a plan view of the substrate, the second contact layer forms an outermost layer opposite to the substrate in the laminated structure, and the electrode layer electrically connects the projecting portion of the first contact layer and the second contact layer. According to this configuration, unit light-emitting elements constituting the light-emitting element array can be compactly connected to each other without the use of wires. By avoiding wire connections, various effects such as improved ease of assembly of semiconductor light-emitting devices, improved ease of mounting in packages, improved yield rate, and lower cost can be achieved.
[6] The semiconductor light-emitting device according to [5], wherein, in one of the unit light-emitting elements, the first contact layer has an additional projecting portion projecting without extending toward the unit light-emitting element of the connection destination from the laminated structure in the plan view of the substrate, and the electrode layer electrically connects the projecting portion and the additional projecting portion of the first contact layer to the second contact layer. In this case, the electrode layer electrically connected to the additional projecting portion of the first contact layer is placed around the unit light-emitting element to ensure uniform electric current injection into the unit light-emitting element. Thereby, it is possible to implement a more uniform laser light output.
[7] The semiconductor light-emitting device according to [6], wherein, in one of the unit light-emitting elements, the laminated structure has a rectangular shape in the plan view of the substrate, and the additional projecting portion projects outside of the laminated structure from one of a pair of edges along an array direction of the plurality of unit light-emitting elements in the plan view of the substrate. In this case, the electrode layer electrically connected to the additional projecting portion of the first contact layer is arranged around the unit light-emitting element in correspondence with one of a pair of edges along the array direction, thereby ensuring uniform electric current injection into the unit light-emitting element. Thereby, it is possible to implement a uniform laser light output while making a compact connection between unit light-emitting elements.
[8] The semiconductor light-emitting device according to [6], wherein, in one of the unit light-emitting elements, the laminated structure has a rectangular shape in the plan view of the substrate, and the additional projecting portion projects outside of the laminated structure from both edges of a pair along an array direction of the plurality of unit light-emitting elements in the plan view of the substrate. In this case, the electrode layer electrically connected to the additional projecting portion of the first contact layer is arranged around the unit light-emitting element in correspondence with both edges of a pair along the array direction, thereby ensuring uniform electric current injection into the unit light-emitting element. Thereby, it is possible to implement a good balance between compactness of the connection between unit light-emitting elements and a uniform laser light output.
[9] The semiconductor light-emitting device according to [6], wherein, in one of the unit light-emitting elements, the laminated structure has a rectangular shape in the plan view of the substrate, and the additional projecting portion projects outside of the laminated structure from both edges of a pair along an array direction of the plurality of unit light-emitting elements in the plan view of the substrate and from a side opposite to the unit light-emitting element of the connection destination. In this case, the electrode layer electrically connected to the additional projecting portion of the first contact layer surrounds the unit light-emitting element, thereby causing the electric current injection into the unit light-emitting element to be further uniform. Thereby, it is possible to implement a more uniform laser light output.
[10] The semiconductor light-emitting device according to any one of [1] to [9], wherein a region where the unit light-emitting elements are located is positioned at a central portion of the substrate, and a connection region between the light-emitting element arrays is positioned at an edge end portion of the substrate. In this case, for example, temperature control of each unit light-emitting element can be suitably implemented by attaching a temperature control device to the region where the unit light-emitting elements are located, while avoiding the connection region between the light-emitting element arrays. Moreover, by separating the region where the unit light-emitting elements are located from the region where the light-emitting element arrays are connected to each other, it is possible to apply an antireflection film to the entire surface where the laser light is emitted and facilitate lens mounting and fiber connection.
[11] The semiconductor light-emitting device according to [1], wherein a semiconductor epitaxial growth layer is provided between the laminated structures of the unit light-emitting elements aligned in an array direction of the plurality of unit light-emitting elements, and wherein the first contact layer of one of the unit light-emitting elements in the array direction is electrically connected to the second contact layer of the adjacent unit light-emitting element in the array direction by the semiconductor epitaxial growth layer and the electrode layer.

In this semiconductor light-emitting device, the semiconductor epitaxial growth layer arranged between the laminated structures of unit light-emitting elements aligned in the array direction allows the laser light generated in one unit light-emitting element to propagate to the adjacent unit light-emitting elements in the array direction. Thereby, it is possible to enable coherent coupling of laser light beams generated by the unit light-emitting elements in the light-emitting element array, thereby improving the directivity and intensity of the laser light.
[12] The semiconductor light-emitting device according to [11], wherein the semiconductor epitaxial growth layer is doped with the same polarity as the first contact layer. According to this configuration, it is possible to suitably implement the electrical series connection between adjacent unit light-emitting elements and coherent coupling between laser light beams generated by adjacent unit light-emitting elements.
[13] The semiconductor light-emitting device according to [11] or [12], wherein the semiconductor epitaxial growth layer and a part other than the first contact layer of one of the laminated structures of the unit light-emitting elements aligned in the array direction are electrically insulated by an insulating layer. According to this configuration, the unit light-emitting elements aligned in the array direction can be connected electrically in series with each other and optically coherently coupled.
[14] The semiconductor light-emitting device according to any one of [11] to [13], wherein, in the light-emitting element array, the unit light-emitting elements are arrayed linearly or arrayed to have one or more bends, and wherein the semiconductor epitaxial growth layer is provided between the laminated structures of the unit light-emitting elements aligned in a crossing direction that crosses the array direction. In this case, the semiconductor epitaxial growth layer arranged between the laminated structures of unit light-emitting elements aligned in the crossing direction allows the laser light generated in one unit light-emitting element to propagate to the adjacent unit light-emitting element in the crossing direction. Thereby, it is possible to further strengthen the coherent coupling between laser light beams generated by the unit light-emitting elements in the light-emitting element array and further improve the directivity and intensity of the laser light.
[15] The semiconductor light-emitting device according to [14], wherein the semiconductor epitaxial growth layer and the laminated structure of the unit light-emitting elements aligned in the crossing direction are electrically insulated by an insulating layer. According to this configuration, it is possible to optically couple the unit light-emitting elements arrayed in the crossing direction in a coherent way while electrically insulating the unit light-emitting elements from each other.

### BRIEF DESCRIPTION OF THE DRAWINGS

FIG. 1 is a plan view of a semiconductor light-emitting device according to an embodiment of the present disclosure.

FIG. 2 is a plan view showing an example of a light-emitting element array.

FIG. 3 is a cross-sectional view showing a connection configuration of unit light-emitting elements constituting the light-emitting element array.

FIG. 4 is a plan view showing an example of an arrangement relationship of a laminated structure of a unit light-emitting element, a first contact layer, a second contact layer, and an electrode layer.

FIG. 5 is a cross-sectional view showing an example of a configuration in which external equipment and the like are arranged with respect to the semiconductor light-emitting device.

FIG. 6 is a plan view showing another example of the positional relationship of the laminated structure of the unit light-emitting element, the first contact layer, the second contact layer, and the electrode layer.

FIG. 7 is a plan view showing yet another example of the positional relationship of the laminated structure of the unit light-emitting element, the first contact layer, the second contact layer, and the electrode layer.

FIG. 8 is a plan view showing yet another example of the positional relationship of the laminated structure of the unit light-emitting element, the first contact layer, the second contact layer, and the electrode layer.

FIG. 9 is a plan view showing yet another example of the positional relationship of the laminated structure of the unit light-emitting element, the first contact layer, the second contact layer, and the electrode layer.

FIG. 10 is a plan view showing another example of the light-emitting element array.

FIG. 11 is a plan view showing yet another example of the light-emitting element array.

FIG. 12 is a diagram showing an example of a configuration of each layer constituting a unit light-emitting element.

FIG. 13 is a diagram showing examples of materials of each layer constituting the unit light-emitting element.

FIG. 14A is an enlarged cross-sectional view of a principal part showing a configuration of a light-emitting element array in a semiconductor light-emitting device according to another example.

FIG. 14B is an enlarged cross-sectional view of a principal part showing a configuration of a light-emitting element array in a semiconductor light-emitting device according to another example.

FIG. 15A is an enlarged cross-sectional view of a principal part showing manufacturing steps of the semiconductor light-emitting device shown in FIGS. 14A and 14B.

FIG. 15B is an enlarged cross-sectional view of a principal part showing manufacturing steps of the semiconductor light-emitting device shown in FIGS. 14A and 14B.

FIG. 16A is an enlarged cross-sectional view of a principal part showing subsequent steps following those of FIGS. 15A and 15B.

FIG. 16B is an enlarged cross-sectional view of a principal part showing subsequent steps following those of FIGS. 15A and 15B.

FIG. 17A is an enlarged cross-sectional view of a principal part showing subsequent steps following those of FIGS. 16A and 16B.

FIG. 17B is an enlarged cross-sectional view of a principal part showing subsequent steps following those of FIGS. 16A and 16B.

FIG. 18A is an enlarged cross-sectional view of a principal part showing subsequent steps following those of FIGS. 17A and 17B.

FIG. 18B is an enlarged cross-sectional view of a principal part showing subsequent steps following those of FIGS. 17A and 17B.

### DETAILED DESCRIPTION

Hereinafter, preferred embodiments of a semiconductor light-emitting device according to an aspect of the present disclosure will be described in detail with reference to the drawings.

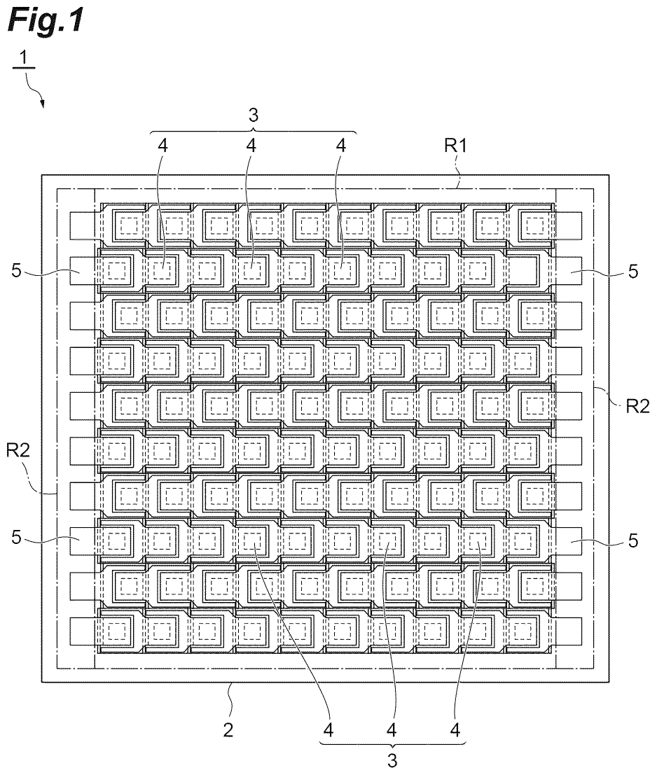

FIG. 1 is a plan view of a semiconductor light-emitting device according to an embodiment of the present disclosure. The semiconductor light-emitting device 1 shown in FIG. 1 is a device including a plurality of unit light-emitting elements 4 referred to as so-called photonic crystal surface emitting lasers (PCSELs). In the present embodiment, the semiconductor light-emitting device 1 comprises a substrate 2 and a light-emitting element array 3. A substrate 2 is a portion that is the base of the semiconductor light-emitting device 1. The substrate 2 may be an insulating substrate or a semi-insulating substrate. The substrate 2 may be a conductive substrate with a high-resistance layer or the like. In the example of FIG. 1, the substrate 2 is a semi-insulating substrate and has a rectangular shape in the plan view.

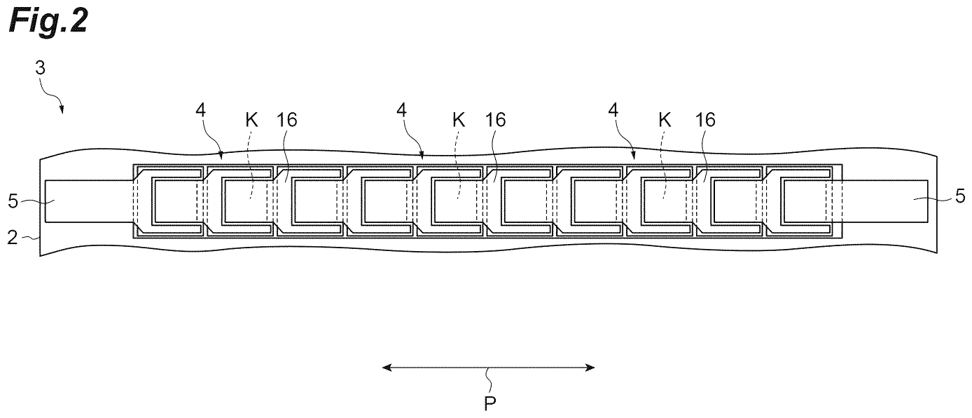

The light-emitting element array 3 is an array structure of a plurality of unit light-emitting elements 4 arrayed in a row, as shown in FIG. 2. In the example of FIG. 2, one light-emitting element array 3 is configured by ten unit light-emitting elements 4 that are arrayed linearly and electrically connected in series with each other. In the semiconductor light-emitting device 1, as shown in FIG. 1, a plurality of light-emitting element arrays 3 are provided on one side of the substrate 2. In the example of FIG. 1, ten linear light-emitting element arrays 3 are arrayed on one surface side of the substrate 2 parallel to each other, with the orientation of the array of the unit light-emitting elements 4 aligned.

At both end portions of each light-emitting element array 3 in the array direction, draw-out electrodes 5 continuous with an electrode layer 16 to be described below are provided. The light-emitting element arrays 3 are electrically connected in parallel to each other via these draw-out electrodes 5 without using wires. With respect to the electrical connection of each light-emitting element array 3, all of the light-emitting element arrays 3 may be electrically connected in parallel to each other, or a plurality of light-emitting element arrays 3 electrically connected in series with each other may be electrically connected in parallel with each other.

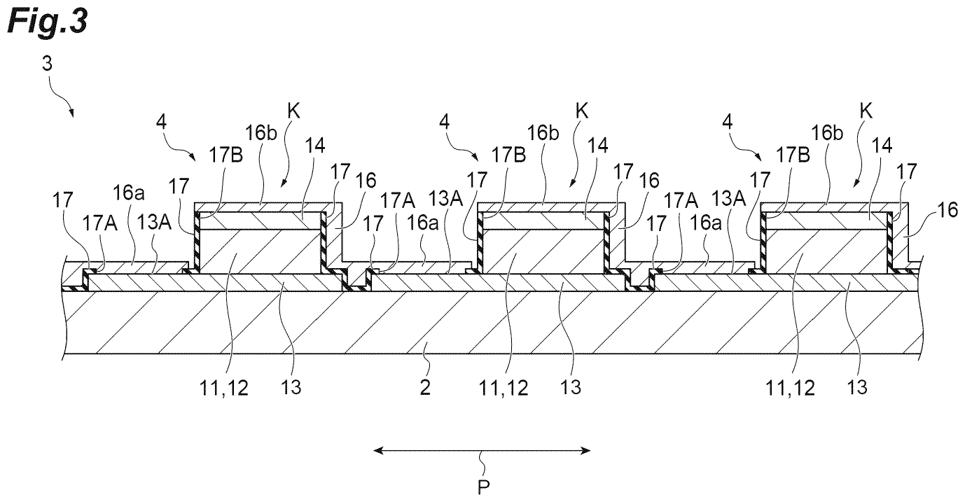

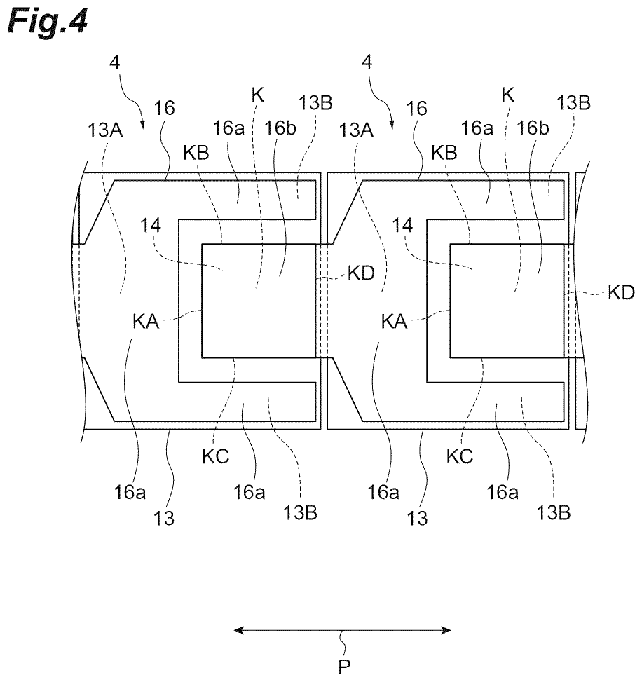

FIG. 3 is a cross-sectional view showing a connection configuration of unit light-emitting elements constituting the light-emitting element array. As shown in FIG. 3, the unit light-emitting element 4 has a laminated structure K that includes an active layer 11, a photonic crystal layer 12, and a first contact layer 13 and a second contact layer 14 that sandwich the active layer 11 and the photonic crystal layer 12. The laminated structure K has a rectangular shape in the plan view of the substrate 2. Here, the laminated structure K has a square shape in the plan view of the substrate 2 (see FIG. 4).

The laminated structure K includes the first contact layer 13, a first cladding layer (not shown), the active layer 11, the photonic crystal layer 12, a second cladding layer (not shown), and the second contact layer 14, laminated in order from the substrate 2 side. At least one of the interfaces between the active layer 11 and the first cladding layer and between the active layer 11 and the second cladding layer may, if necessary, be provided with an optical guide layer for adjusting light confinement. The optical guide layer may include a carrier barrier layer for efficiently confining carriers in the active layer 11.

The first contact layer 13, the first cladding layer, the active layer 11, the second cladding layer, and the second contact layer 14 include, for example, compound semiconductors such as GaAs-based semiconductors, InP-based semiconductors, or nitride-based semiconductors. The active layer 11, for example, has a multiple quantum well structure. The refractive indices of the first and second cladding layers are smaller than that of the active layer 11.

The photonic crystal layer 12 is a layer whose refractive index changes periodically and is optically coupled to the active layer 11. The photonic crystal layer 12, for example, functions as a phase control layer that controls the phase of light generated in the active layer 11. The photonic crystal layer 12 contains a plurality of phase control regions. Each of the phase control regions is configured to include a region having a first refractive index (basic refractive index region) and a region having a second refractive index different from the first refractive index (different refractive index region). The basic refractive index region includes, for example, compound semiconductors such as GaAs-based semiconductors, InP-based semiconductors, and nitride-based semiconductors. The different refractive index regions, for example, include voids, and are distributed two-dimensionally within the basic refractive index region.

A wavelength selected by the phase control region is included within a range of emission wavelengths of the active layer 11. The phase control region selects and externally outputs a component of the light generated in the active layer 11 corresponding to a band-edge wavelength near a wavelength selected by the phase control region. Light incident on each phase control region from the active layer 11 forms a mode according to the arrangement of the different refractive index regions within each phase control region and is output from the unit light-emitting element 4 as laser light.

In the light-emitting element array 3, an electrode layer 16 is used for an electrical connection between the unit light-emitting elements 4. In the light-emitting element array 3, as shown in FIG. 3, the first contact layer 13 of one unit light-emitting element 4 is electrically connected to the second contact layer 14 of the adjacent unit light-emitting element 4 by the electrode layer 16.

The first contact layer 13 is the outermost layer on the substrate 2 side in the laminated structure K. The first contact layer 13 corresponds to the shape of the laminated structure K and is square in the plan view of the substrate 2. The planar shape of the first contact layer 13 may be slightly larger than the planar shape of the laminated structure K. The first contact layer 13 has a projecting portion 13A that projects toward the unit light-emitting element 4 of the connection destination from the laminated structure K in the plan view of the substrate 2. The projecting portion 13A projects from an edge KA (see FIG. 4) serving as the unit light-emitting element 4 side of the connection destination in the laminated structure K, toward the unit light-emitting element 4 of the connection destination. The planar shape of the projecting portion 13A is not particularly limited, but is, for example, rectangular.

The second contact layer 14 is the outermost layer opposite to the substrate 2 in the laminated structure K. Like the first contact layer 13, the second contact layer 14 corresponds to the shape of the laminated structure K and is square in the plan view of the substrate 2.

An insulating layer 17 is provided on the surface of the projecting portion 13A of the first contact layer 13 and the surface of the second contact layer 14. The insulating layer 17, for example, includes a material having electrical insulation properties, such as silicon nitride or silicon oxide. In the present embodiment, as shown in FIG. 3, the insulating layer 17 is provided not only on the surface of the projecting portion 13A of the first contact layer 13 and the surface of the second contact layer 14, but also on the front surface of one surface side of the substrate 2 exposed from the unit light-emitting element 4, the side surface of the first contact layer 13 (the side surface extending in the lamination direction), and the side surface of the laminated structure K (the side surface extending in the lamination direction).

An opening 17A for exposing the projecting portion 13A is provided in the insulating layer 17 on the surface of the projecting portion 13A of the first contact layer 13. An opening 17B for exposing the second contact layer 14 is provided in the insulating layer 17 on the front surface of the second contact layer 14. The planar shapes of the openings 17A and 17B are not particularly limited and may be appropriately selected from various shapes such as rectangular, circular, polygonal, and oval shapes.

The electrode layer 16, for example, is made of a highly conductive metal material such as gold. The electrode layer 16 may include a plurality of metal layers in accordance with the material of the first contact layer 13 or the second contact layer 14. Combinations of a plurality of metal layers include, for example, Au/Ti, Au/Pt/Ni, Au/Ti/Al, and the like. In the visible light region, ZnO, indium tin oxide (ITO), and the like may be used. One end portion 16a of the electrode layer 16 is arranged to overlap the insulating layer 17 on the front surface of the projecting portion 13A in one unit light-emitting element 4 and is ohmically connected to the first contact layer 13 via the opening 17A.

The electrode layer 16 extends across the insulating layer 17 of the front surface of one surface side of the substrate 2 toward the unit light-emitting element 4 adjacent to one unit light-emitting element 4. The electrode layer 16 extends to the front surface of the second contact layer 14 in the adjacent unit light-emitting element 4 over the front surface of the insulating layer 17 positioned on the side surface of the laminated structure K in the adjacent unit light-emitting element 4. The other end portion 16b of the electrode layer 16 is arranged to overlap the insulating layer 17 of the front surface of the second contact layer 14 in the adjacent unit light-emitting element 4 and is ohmic-connected to the second contact layer 14 via the opening 17B.

In the present embodiment, as shown in FIG. 4, in one unit light-emitting element 4, the first contact layer 13 has an additional projecting portion 13B that projects without extending toward the unit light-emitting element 4 of the connection destination from the laminated structure K in the plan view of the substrate 2. The electrode layer 16 electrically connects the projecting portion 13A and the additional projecting portion 13B of the first contact layer 13 to the second contact layer 14. In the example of FIG. 4, in one unit light-emitting element 4, the additional projecting portion 13B projects outside of the laminated structure K from both edges KB and KC of a pair along the array direction P of the plurality of unit light-emitting elements 4 in the plan view of the substrate 2.

One end portion 16a of the electrode layer 16, which is arranged to overlap the insulating layer 17 on the surface of the projecting portion 13A along the edge KA of the laminated structure K, splits into two branches and extends to the respective front surfaces of the additional projecting portions 13B and 13B that project from both edges KB and KC of the laminated structure K. Thereby, one end portion 16a of the electrode layer 16 is C-shaped in the plan view of the substrate 2, along the edges KA, KB, and KC of the laminated structure K. The insulating layer 17 is provided on the front surface of the additional projecting portions 13B and 13B similarly to the surface of the projecting portion 13A, and the opening 17A is formed to extend over these portions. One end portion 16a of the electrode layer 16, which is arranged to overlap the insulating layer 17 on the surface of the additional projecting portions 13B and 13B, is ohmic-connected to the first contact layer 13 via the opening 17A.

As described above, in the semiconductor light-emitting device 1, by electrically connecting the first contact layer 13 of one unit light-emitting element 4 to the second contact layer 14 of the adjacent unit light-emitting element 4 by means of the electrode layer 16, a plurality of light-emitting element arrays 3 in which a plurality of unit light-emitting elements 4 are arrayed in a row are configured. According to this configuration, the element size of each unit light-emitting element 4 can be sufficiently ensured, and the influence of a Fabry-Perot resonance mode between the end surfaces of the elements can be reduced. By providing a plurality of such light-emitting element arrays 3 on the substrate 2, high-output-power and uniform laser light can be extracted.

In the present embodiment, a plurality of light-emitting element arrays 3 are electrically connected in parallel to each other. Thereby, a plurality of light-emitting element arrays 3 are electrically connected in parallel, thereby enabling laser light to be extracted from each unit light-emitting element 4 while eliminating an influence of warping of the substrate 2 due to heat generated during driving and a problem such as mode competition. Thereby, the laser light with desired characteristics can be extracted at high output power. Moreover, replacement of the light-emitting element array 3 and mounting of fuse elements can be easily implemented.

In the present embodiment, the unit light-emitting elements 4 are linearly arranged in the light-emitting element array 3. Thereby, the light-emitting element array 3 can be efficiently arranged on the substrate 2. Moreover, the electrical connection between the light-emitting element arrays 3 can be implemented at the array end portion of the light-emitting element arrays 3. Thereby, because it is possible to clearly separate a region R1 where the unit light-emitting elements 4 are located on the substrate 2 from a connection region R2 between the light-emitting element arrays 3, uniform temperature control of the region of the unit light-emitting elements 4 is enabled and a more uniform laser light output is implemented.

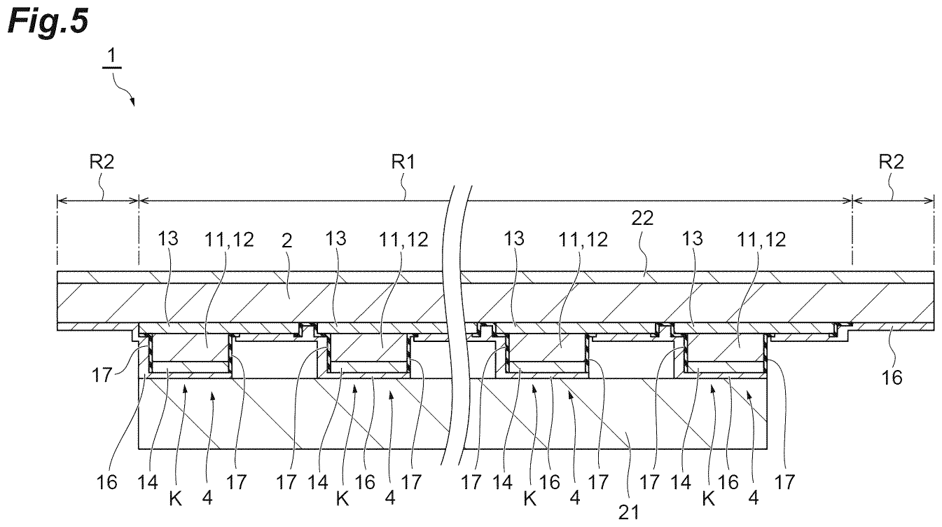

For example, in an array of light-emitting element arrays 3 as shown in FIG. 1, the region R1 where the unit light-emitting elements 4 are located can be positioned in the center portion of the substrate 2, and the connection region R2 between the light-emitting element arrays 3 can be positioned at both end portions (edge end portions) of the substrate 2. In this case, as shown in FIG. 5, the temperature control of each unit light-emitting element 4 can be suitably implemented by attaching the temperature control device 21 to the region R1 where the unit light-emitting elements 4 are located while avoiding the connection region R2 between the light-emitting element arrays 3. Moreover, by separating the region R1 where the unit light-emitting elements 4 are located from the connection region R2 between the light-emitting element arrays 3, it is possible to apply an antireflection film 22 to the entire emission surface of the laser light and also facilitate the lens mounting and fiber connection.

In the present embodiment, in one unit light-emitting element 4, the first contact layer 13 forms the outermost layer on the substrate 2 side in the laminated structure K and has a projecting portion 13A that projects toward the unit light-emitting element 4 of the connection destination from the laminated structure K in the plan view of the substrate 2. Moreover, the second contact layer 14 forms the outermost layer opposite to the substrate in the laminated structure K and the electrode layer 16 electrically connects the projecting portion 13A of the first contact layer 13 to the second contact layer 14 of the adjacent unit light-emitting element. According to this configuration, unit light-emitting elements 4 that make up the light-emitting element array 3 can be compactly connected to each other without the use of wires. By avoiding wire connections, various effects such as improved ease of assembly of the semiconductor light-emitting device 1, improved ease of mounting in packages, improved yield rate, and lower cost can be achieved.

In the present embodiment, in one unit light-emitting element 4, the first contact layer 13 has an additional projecting portion 13B that projects without extending toward the unit light-emitting element 4 of the connection destination from the laminated structure K in the plan view of the substrate 2. Moreover, the electrode layer 16 electrically connects the projecting portion 13A and the additional projecting portion 13B of the first contact layer 13 to the second contact layer 14. According to this configuration, the electrode layer 16 electrically connected to the additional projecting portion 13B of the first contact layer 13 is arranged around the unit light-emitting element 4 to ensure uniform electric current injection into the unit light-emitting element 4. Thereby, a more uniform laser light output can be implemented.

In the present embodiment, in one unit light-emitting element 4, the laminated structure K is rectangular in the plan view of the substrate 2. Also, the additional projecting portion 13B projects outside of the laminated structure K from both edges KB and KC of the pair along the array direction of the plurality of unit light-emitting elements 4 in the plan view of the substrate 2. In this case, the electrode layer 16 electrically connected to the additional projecting portion 13B of the first contact layer 13 is arranged around the unit light-emitting element 4 in correspondence with both edges KB and KC of the pair along the array direction, to ensure uniform electric current injection to the unit light-emitting element 4. Thereby, it is possible to implement a good balance between compactness of the connection between the unit light-emitting elements 4 and uniform laser light output.

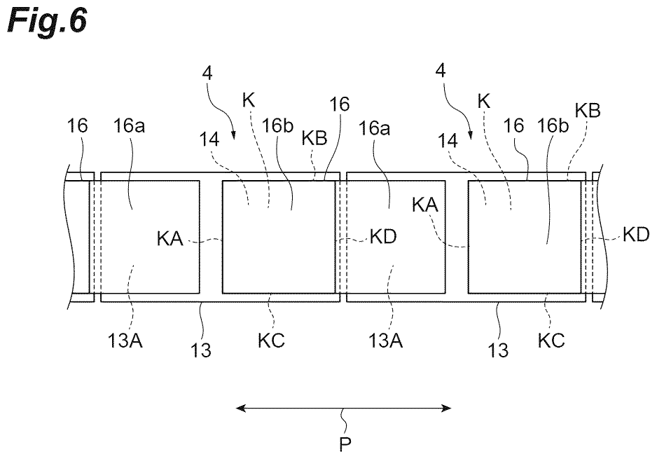

The present disclosure is not limited to the above-described embodiment. For example, the arrangement of the first contact layer 13 and electrode layer 16 in the plan view of substrate 2 is not limited to the C-shaped example shown in FIG. 4, and various configurations may be adopted. For example, as in the shortest type shown in FIG. 6, a configuration in which the first contact layer 13 has only a projecting portion 13A that projects from the edge KA of the laminated structure K and there is no additional projecting portion 13B may be provided. In this case, the connection between unit light-emitting elements can be sufficiently compact.

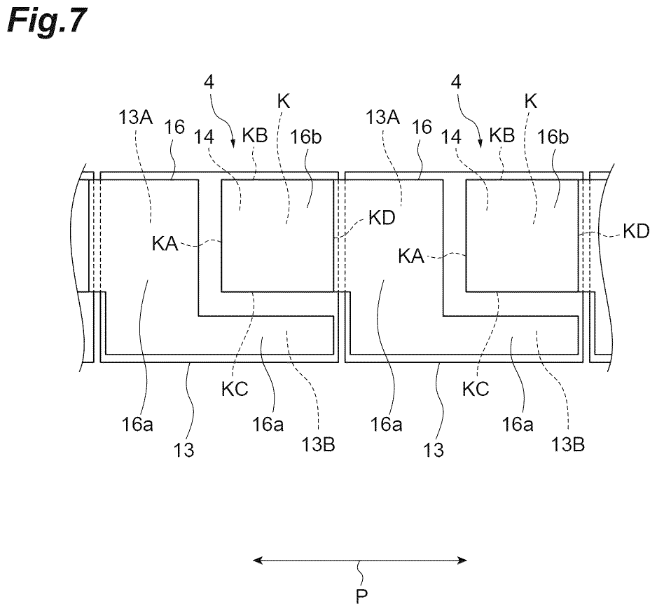

As in the L-shaped example shown in FIG. 7, the additional projecting portion 13B may be configured to project outside of the laminated structure from one of the pair of edges KB and KC (the edge KC in FIG. 7) along the array direction P of the plurality of unit light-emitting elements 4 in the plan view of the substrate 2. According to this configuration, the electrode layer 16 electrically connected to the additional projecting portion 13B of the first contact layer 13 in correspondence with one of a pair of edges KB and KC along the array direction, thereby ensuring uniform electric current injection into the unit light-emitting element 4. Thereby, it is possible to implement a compact connection between the unit light-emitting elements 4 while achieving uniform laser light output.

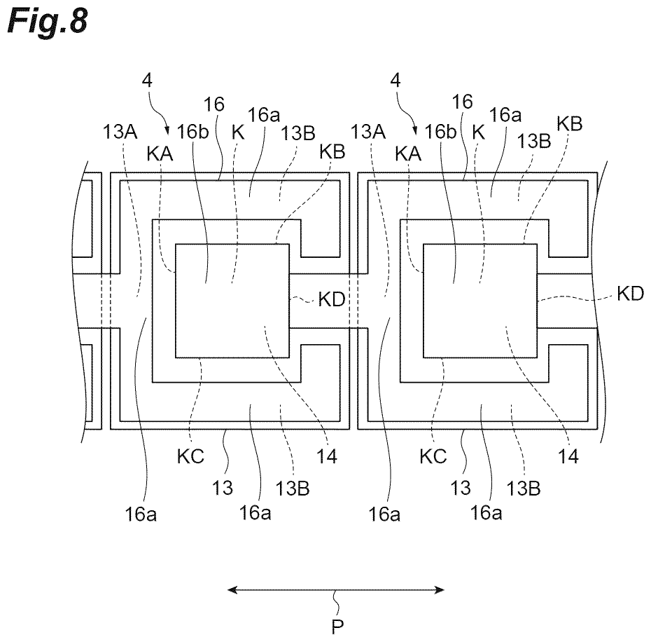

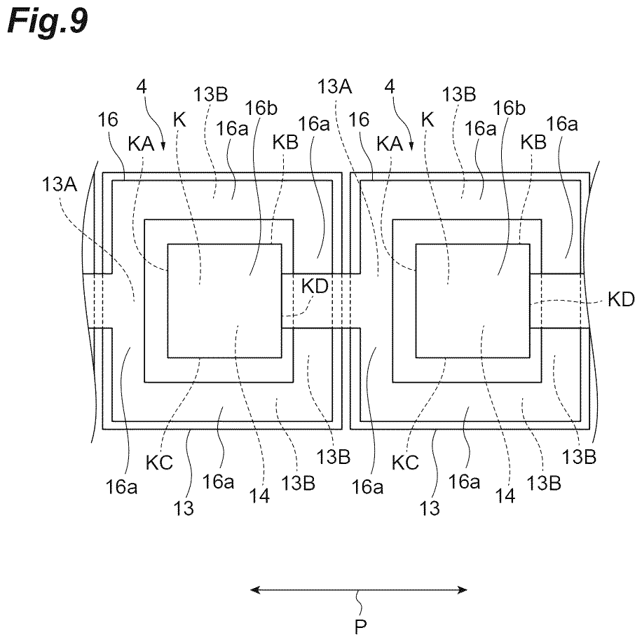

As in the hook type example shown in FIG. 8 or the full circumference type example shown in FIG. 9, the additional projecting portion 13B may be configured to project outside of the laminated structure K from both edges KB and KC of the pair along the array direction P of the plurality of unit light-emitting elements 4 in the plan view of the substrate 2 and from the edge KD opposite to the unit light-emitting elements 4 of the connection destination. In the example in FIG. 8, one end portion 16a of the electrode layer 16 is hooked along the edges KA, KB, and KC of the laminated structure K, with its distal end part wrapping around a portion of the edge KD.

Moreover, in the example of FIG. 9, one end portion 16a of the electrode layer 16 is arranged to surround the entire laminated structure K along all of the edges KA to KD of the laminated structure K. At an overlapping portion between one end portion 16a of the electrode layer 16 along the edge KD and the electrode layer 16 toward the unit light-emitting element 4 of the connection destination, for example, a bridge structure where one is arranged on the other via an insulating layer 17 can be adopted. According to the configuration shown in FIGS. 8 and 9, the electrode layer 16 electrically connected to the additional projecting portion 13B of the first contact layer 13 surrounds the unit light-emitting element 4, thereby ensuring further uniformity of electric current injection into the unit light-emitting element 4. Thereby, a more uniform laser light output can be implemented.

With respect to the arrangement of the first contact layer 13 and the electrode layer 16 described above, in terms of compactness of the connection between unit light-emitting elements 4, the shortest type, L-shaped, C-shaped, hook-shaped, and full circumference type are considered to be highly effective, in that order. Moreover, in terms of uniformity of electric current injection into the unit light-emitting element 4, it is considered that higher effects are achieved in the order of full circumference type, hook type, C-shaped type, L-shaped type, and shortest type. Furthermore, in terms of process complexity, the process is expected to become more complex in the order of shortest type, L-shaped, C-shaped, hooked type, and full circumference type. From the viewpoint of achieving a good balance between compactness of connection between unit light-emitting elements, uniform laser light output, and avoidance of process complexity, the C-shaped type may be adopted.

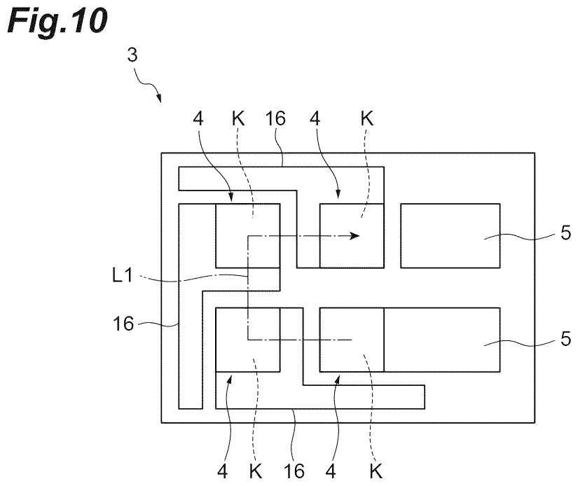

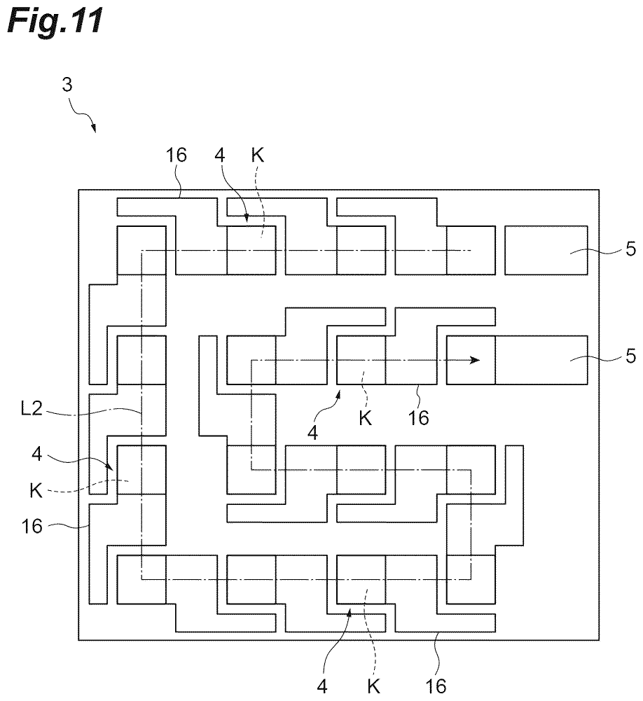

Although an example of a linear array structure is shown as a configuration in which the unit light-emitting elements 4 are aligned in an array in the light-emitting element array 3, for example, in the above-described embodiment, the unit light-emitting elements 4 may be arrayed with one or more bends in the light-emitting element array 3 as shown in FIGS. 10 and 11. In other words, in the light-emitting element array 3, the unit light-emitting elements 4 may be arrayed in a row that allows a single stroke to be made.

In the example of FIG. 10, one light-emitting element array 3 is configured by electrically connecting four unit light-emitting elements 4, which are arranged in a 2×2 grid shape, in series with each other so as to form a C-shaped line L1. In the example of FIG. 11, one light-emitting element array 3 is configured by electrically connecting sixteen unit light-emitting elements 4, which are arranged in a 4×4 grid pattern, in series with each other so as to form a spiral line L2 having six bends.

In the examples in FIGS. 10 and 11, the draw-out electrodes at both end portions of the array direction of each light-emitting element array 3 are drawn out in the same direction. Therefore, because the region R1 where the unit light-emitting elements 4 are located and the connection region R2 between the light-emitting element arrays 3 can be clearly separated on the substrate 2, the region where the unit light-emitting elements 4 are located can be uniformly controlled in temperature, enabling a more uniform laser light output.

Although an example in which the plurality of light-emitting element arrays 3 are electrically connected in parallel has been described in the above-described embodiment, the present invention is not limited thereto and an aspect in which the plurality of light-emitting element arrays 3 are electrically connected in series may be provided. In this aspect, the element size of each unit light-emitting element 4 can still be sufficiently ensured to reduce the influences of Fabry-Perot resonance modes between the end surfaces of the elements. By providing a plurality of light-emitting element arrays 3 on the substrate 2, high-output-power and uniform laser light can be extracted.

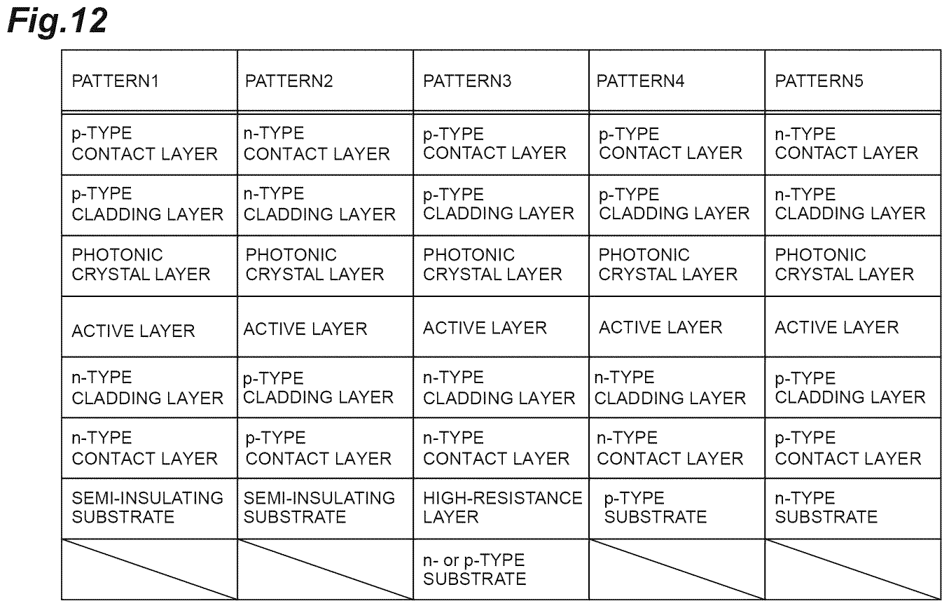

FIG. 12 is a diagram showing an example of a configuration of each layer constituting a unit light-emitting element. As shown in FIG. 12, in pattern 1, an n-type contact layer, an n-type cladding layer, an active layer, a photonic crystal layer, a p-type cladding layer, and a p-type contact layer are laminated in that order on one surface side of the semi-insulating substrate. In pattern 2, conductivity types of a contact layer and a cladding layer are reversed from pattern 1 and a p-type contact layer, a p-type cladding layer, an active layer, a photonic crystal layer, an n-type cladding layer, and an n-type contact layer are laminated in that order on one surface side of the semi-insulating substrate.

In pattern 3, a high-resistance layer is provided on one surface side of an n-or p-type conductive substrate, and an n-type contact layer, an n-type cladding layer, an active layer, a photonic crystal layer, a p-type cladding layer, and a p-type contact layer are laminated in that order on the high-resistance layer. The high-resistance layer may be a single layer or multilayered. In pattern 4, an n-type contact layer, an n-type cladding layer, an active layer, a photonic crystal layer, a p-type cladding layer, and a p-type contact layer are laminated in that order on one surface side of the p-type conductive substrate. In pattern 5, conductivity types of a substrate and a contact layer are reversed from pattern 4, and a p-type contact layer, a p-type cladding layer, an active layer, a photonic crystal layer, an n-type cladding layer, and an n-type contact layer are laminated in that order on one surface side of the n-type conductive substrate.

Although the photonic crystal layer is located on a layer above the active layer (on a layer opposite to the substrate) in the unit light-emitting elements of patterns 1 to 5, the active layer may be located on a layer above the photonic crystal layer (on a layer opposite to the substrate) in the unit light-emitting elements of patterns 1 to 5.

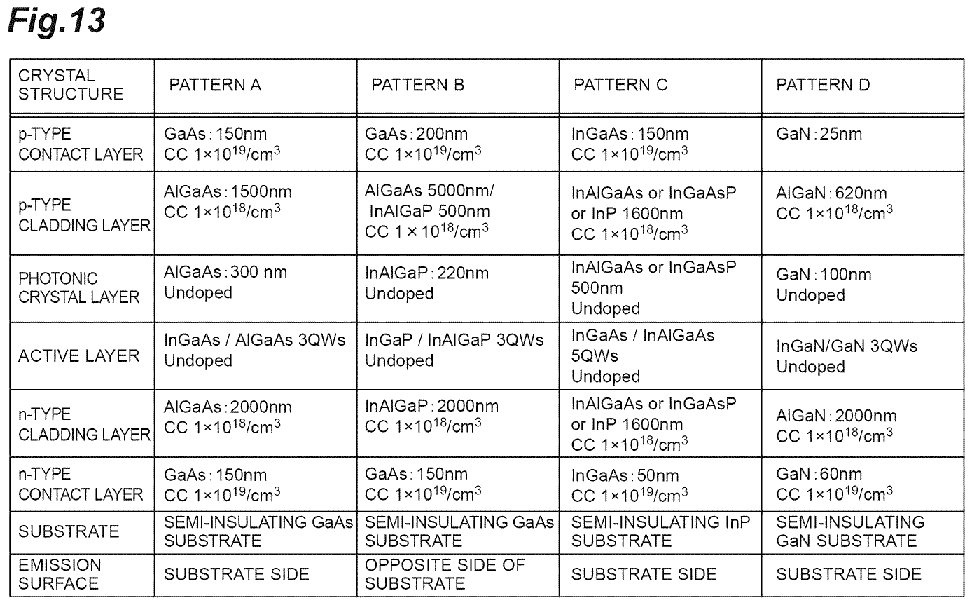

FIG. 13 is a diagram showing an example of a material of each layer constituting the unit light-emitting element. Here, an example of materials for constructing four unit light-emitting elements with different oscillation wavelengths in the layer configuration of pattern 1 of FIG. 12 is shown. Pattern A is an example of a material for a unit light-emitting element with an oscillation wavelength 2 of 980 nm. In pattern A, the substrate is a semi-insulating GaAs substrate; the n-type contact layer has GaAs with a thickness of 150 nm and a carrier concentration of 1×10¹⁹/cm³; the n-type cladding layer has AlGaAs with a thickness of 2000 nm and a carrier concentration of 1×10¹⁸/cm³; the active layer has an undoped InGaAs/AlGaAs (three quantum wells); the photonic crystal layer has an undoped AlGaAs with a thickness of 300 nm; the p-type cladding layer has AlGaAs with a thickness of 1500 nm and a carrier concentration of 1×10¹⁸/cm³; and the p-type contact layer has GaAs having a thickness of 150 nm and a carrier concentration of 1×10¹⁹/cm³. The emission surface of the laser light is the substrate side.

Pattern B is an example of a material for a unit light-emitting element with an oscillation wavelength 2 of 660 nm. In pattern B, the substrate is a semi-insulating GaAs substrate, the n-type contact layer has GaAs with a thickness of 150 nm and a carrier concentration of 1×10¹⁹/cm³, the n-type cladding layer has InAlGaP with a thickness of 2000 nm and a carrier concentration of 1×10¹⁸/cm³, the active layer has undoped InGaP/InAlGaP (three quantum wells), the photonic crystal layer has undoped InAlGaP with a thickness of 220 nm, the p-type cladding layer has a two-layer structure of AlGaAs with a thickness of 5000 nm and a carrier concentration of 1×10¹⁸/cm³ and InAlGaP with a thickness of 500 nm and a carrier concentration of 1×10¹⁸/cm³; and a p-type contact layer has GaAs with a thickness of 200 nm and a carrier concentration of 1×10¹⁹/cm³. The emission surface of the laser light is the opposite side of the substrate.

Pattern C is an example of a material for a unit light-emitting element with an oscillation wavelength 2 of 1550 nm. In pattern C, the substrate is a semi-insulating InP substrate; the n-type contact layer has InGaAs with a thickness of 50 nm and a carrier concentration of 1×10¹⁹/cm³; the n-type cladding layer has InAlGaAs, InGaAsP, or InP with a thickness of 1600 nm and a carrier concentration of 1×10¹⁸/cm³; the active layer has an undoped InGaAs/InAlGaAs (five quantum wells); the photonic crystal layer has an undoped InAlGaAs or InGaAsP with a thickness of 500 nm; the p-type cladding layer has InAlGaAs, InGaAsP, or InP with a thickness of 1600 nm and a carrier concentration of 1×10¹⁸/cm³; and the p-type contact layer has InGaAs with a thickness of 150 nm and a carrier concentration of 1×10¹⁹/cm³. The emission surface of the laser light is the substrate side.

Pattern D is an example of a material for a unit light-emitting element with an oscillation wavelength 2 of 430 nm. In pattern D, the substrate is a semi-insulating GaN substrate; the n-type contact layer has GaN with a thickness of 60 nm and a carrier concentration of 1×10¹⁹/cm³; the n-type cladding layer has AlGaN with a thickness of 2000 nm and a carrier concentration of 1×10¹⁸/cm³; the active layer has an undoped InGaN/GaN (three quantum wells); the photonic crystal layer has an undoped GaN with a thickness of 100 nm; the p-type cladding layer has AlGaN with a thickness of 620 nm and a carrier concentration of 1×10¹⁸/cm³; and the p-type contact layer has GaN with a thickness of 25 nm. The emission surface of the laser light is the substrate side.

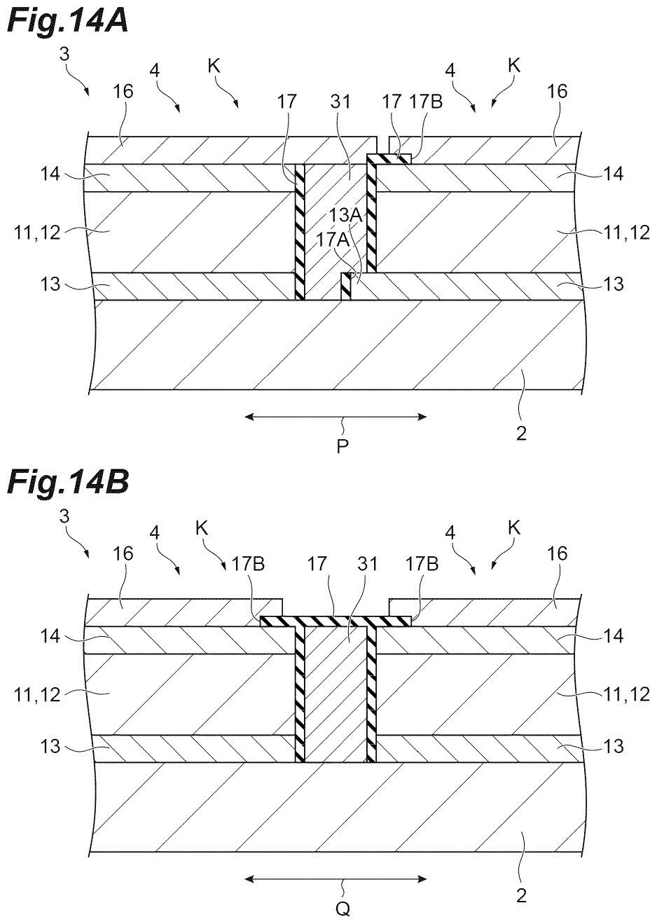

The present disclosure includes yet another aspect. FIGS. 14A and 14B are enlarged cross-sectional views of a principal part showing a configuration of a light-emitting element array in a semiconductor light-emitting device according to other examples. In the aspects shown in FIGS. 14A and 14B, the semiconductor epitaxial growth layer 31 is provided between the laminated structures K of the plurality of unit light-emitting elements 4 aligned in the array direction P of the plurality of unit light-emitting elements 4.

In this aspect, in the light-emitting element array 3, the unit light-emitting elements 4 are arranged with one or more bends. As an example, the unit light-emitting elements 4 may be arrayed in the aspect shown in FIG. 1 or in the aspect shown in FIG. 11. FIG. 14A is a cross-sectional view of the light-emitting element array 3 cut along the array direction P and FIG. 14B is a cross-sectional view of the light-emitting element array 3 cut along the crossing direction Q, which crosses the array direction P. Here, the crossing direction Q is a direction orthogonal to the array direction P in an in-plane direction of the substrate 2.

As shown in FIGS. 14A and 14B, in this aspect, the laminated structure K also includes a first contact layer 13, a first cladding layer (not shown), an active layer 11, a photonic crystal layer 12, a second cladding layer (not shown), and a second contact layer 14, laminated in order from the substrate 2 side. As shown in FIG. 14A, when viewed in the array direction P, the first contact layer 13 has a projecting portion 13A that projects from the laminated structure K toward the unit light-emitting element 4 of the connection destination in the plan view of the substrate 2.

The semiconductor epitaxial growth layer 31 and a portion excluding the first contact layer 13 of one of the laminated structures K of the unit light-emitting elements 4 aligned in the array direction P are electrically insulated by the insulating layer 17. The insulating layer 17 is provided not only on the front surface of the projecting portion 13A of the first contact layer 13 and the front surface of the second contact layer 14, but also on the side surface of the first contact layer 13 (the side surface extending in the lamination direction) and the side surface of the laminated structure K (the side surface extending in the lamination direction). The opening 17A for exposing the projecting portion 13A is provided in the insulating layer 17 on the front surface of the projecting portion 13A of the first contact layer 13. The opening 17B for exposing the second contact layer 14 is provided in the insulating layer 17 on the surface of the second contact layer 14.

The electrode layer 16 is arranged to overlap the second contact layer 14 and is ohmic-connected to the second contact layer 14 via the opening 17B. The electrode layer 16 is extended toward another unit light-emitting element 4 adjacent to the one unit light-emitting element 4 in the array direction P while contacting the semiconductor epitaxial growth layer 31 to be described below, and is arranged to overlap the insulating layer 17 on the front surface of the second contact layer 14 in the adjacent unit light-emitting element 4.

The semiconductor epitaxial growth layer 31 is provided between the laminated structures K of the unit light-emitting elements 4 aligned in the array direction P. In the example in FIG. 14A, the semiconductor epitaxial growth layer 31 is at a height from the front surface of the substrate 2 to the front surface of the second contact layer 14 to fill a gap between the laminated structures K. The semiconductor epitaxial growth layer 31 contacts the first contact layer 13 of the one unit light-emitting element 4 via the opening 17A of the insulating layer 17, and also contacts the electrode layer 16 of the unit light-emitting element 4 of the connection destination. Thereby, the first contact layer 13 of one unit light-emitting element 4 in the array direction P is electrically connected to the second contact layer 14 of the adjacent unit light-emitting element 4 in the array direction P by the semiconductor epitaxial growth layer 31 and electrode layer 16.

The semiconductor epitaxial growth layer 31 includes a compound semiconductor such as, for example, a GaAs-based semiconductor, an InP-based semiconductor, or a nitride-based semiconductor. The semiconductor epitaxial growth layer 31 is doped with the same polarity as the first contact layer 13. For example, when the polarity of the first contact layer 13 is n-type, the polarity of the semiconductor epitaxial growth layer 31 is also n-type. As an example, when the first contact layer 13 includes n-GaAs, the semiconductor epitaxial growth layer 31 includes n-GaAs.

As shown in FIG. 14B, in the crossing direction Q, the semiconductor epitaxial growth layer 31 is also provided between the laminated structures K of the unit light-emitting elements 4 aligned in the crossing direction Q. In the crossing direction Q, the insulating layer 17 covers the top surface of the semiconductor epitaxial growth layer 31 (a surface opposite to the substrate 2). In other words, in the crossing direction Q, unlike the array direction P, the semiconductor epitaxial growth layer 31 and the laminated structure K of the unit light-emitting elements 4 aligned in the crossing direction Q are electrically insulated by the insulating layer 17.

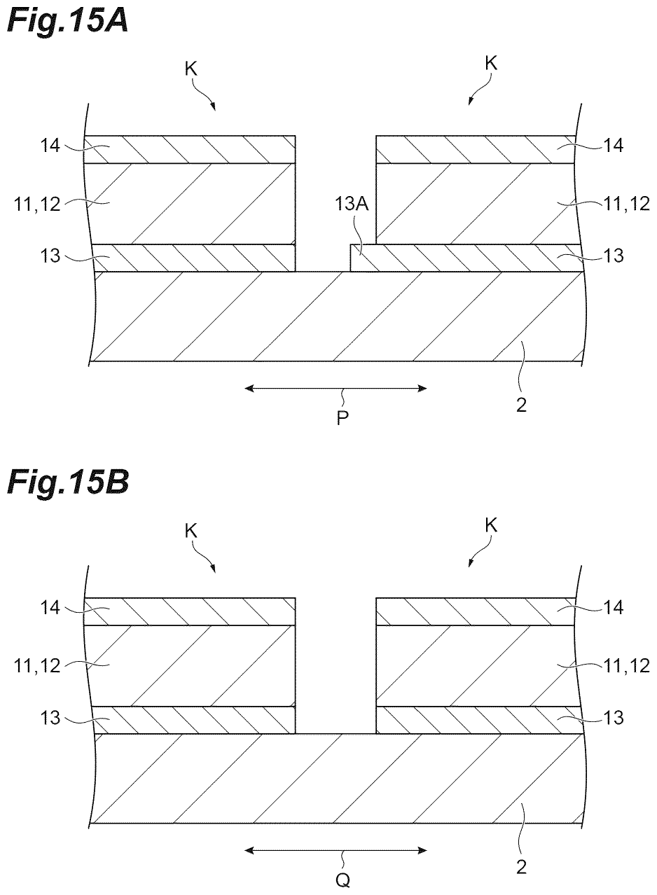

To manufacture the semiconductor light-emitting device 1 in the aspects of FIGS. 14A and 14B, first, the first contact layer 13, the first cladding layer (not shown), the active layer 11, the photonic crystal layer 12, the second cladding layer (not shown), and the second contact layer 14 are formed on the substrate 2 in that order, as shown in FIGS. 15A and 15B. For example, photolithography and etching are used to separate the laminated structures K corresponding to the unit light-emitting elements 4 from each other.

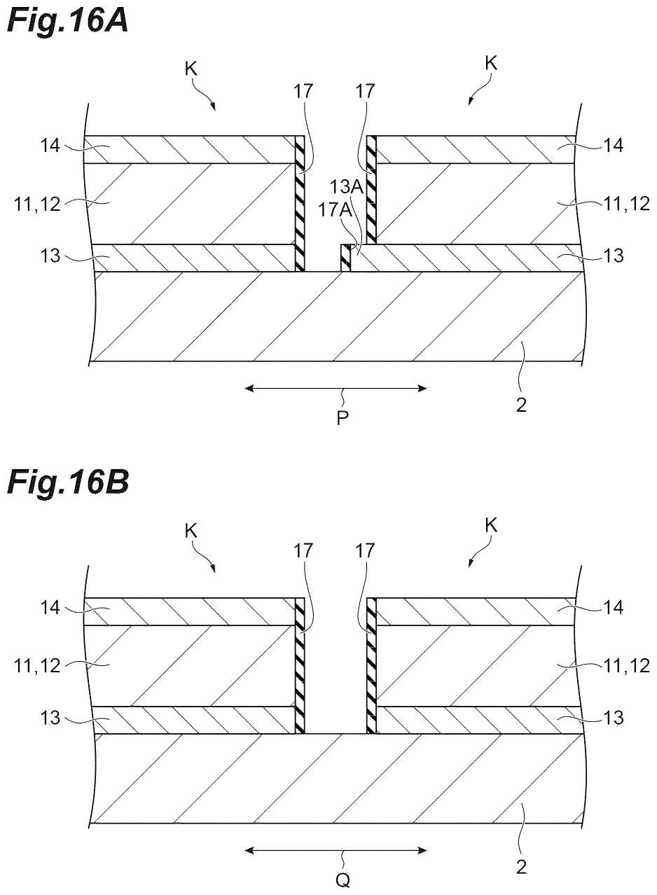

Subsequently, the insulating layer 17 is deposited to cover the substrate 2 and the laminated structure K, for example, by a plasma chemical vapor deposition method. After the deposition of the insulating layer 17, the insulating layer 17 is patterned by, for example, photolithography and etching to remove the insulating layer 17 on the substrate 2, remove the insulating layer 17 on the second contact layer 14, and form the opening 17A, as shown in FIGS. 16A and 16B.

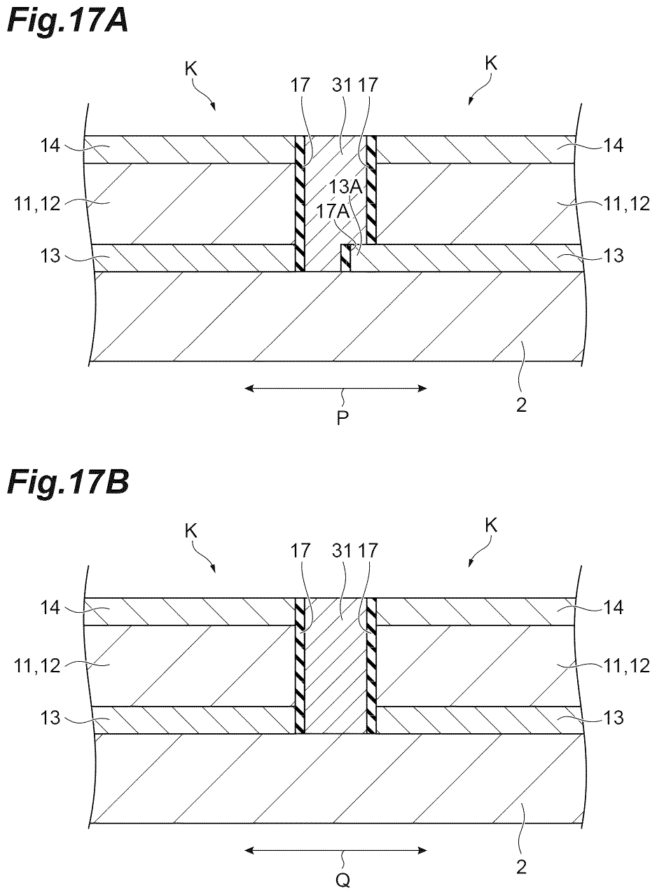

After the insulating layer 17 is patterned, the semiconductor epitaxial growth layer 31 is regrown between the laminated structures K aligned in the array direction P and the laminated structures K aligned in the crossing direction Q, as shown in FIGS. 17A and 17B, for example, by a metal organic chemical vapor deposition method. After the semiconductor epitaxial growth layer 31 is regrown, the insulating layer 17 is deposited again to cover the second contact layer 14 and the semiconductor epitaxial growth layer 31, for example, by a plasma chemical vapor deposition method.

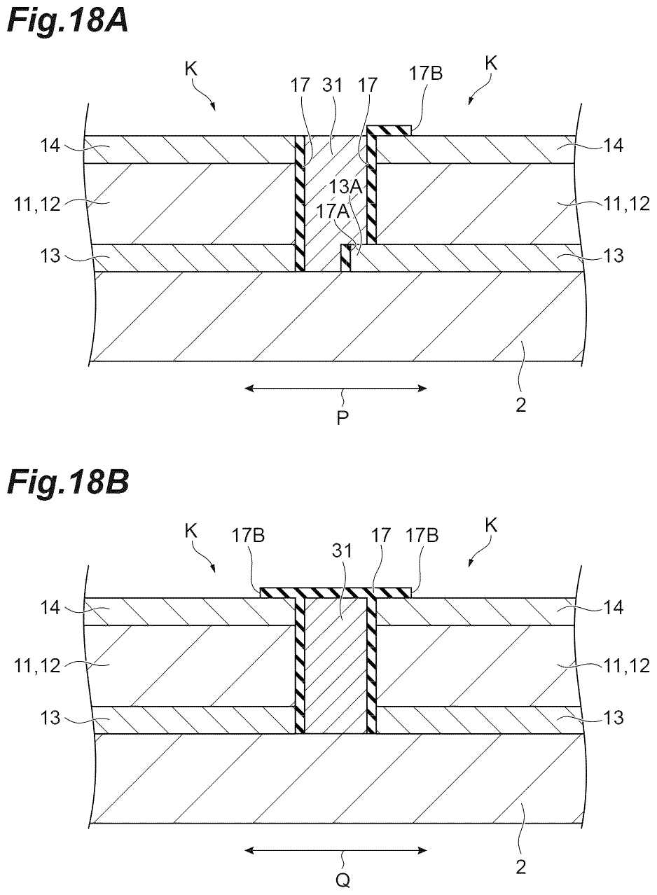

After the deposition of this insulating layer 17, the insulating layer 17 is patterned by, for example, photolithography and etching to remove the insulating layer 17 on the semiconductor epitaxial growth layer 31 between the laminated structures K aligned in the array direction P and to form the opening 17B for the laminated structure K aligned in the crossing direction Q as shown in FIGS. 18A and 18B. Subsequently, the electrode layer 16 in contact with the second contact layer 14 and the semiconductor epitaxial growth layer 31 is formed by, for example, photolithography, vacuum evaporation, and lift-off to obtain the semiconductor light-emitting device 1 in the aspect shown in FIGS. 14A and 14B.

In the semiconductor light-emitting device 1 with the above-described configuration, the semiconductor epitaxial growth layer 31 arranged between the laminated structures K of the unit light-emitting elements 4 aligned in the array direction P can allow the laser light generated in one unit light-emitting element 4 to propagate to the adjacent unit light-emitting elements 4 in the array direction P. Thereby, it is possible to enable coherent coupling of laser light beams generated by the unit light-emitting elements 4 in the light-emitting element array 3, thereby improving the directivity and intensity of the laser light.

In the above-described aspect, the semiconductor epitaxial growth layer 31 is doped with the same polarity as the first contact layer 13. This configuration can suitably implement the electrical series connection between adjacent unit light-emitting elements 4 and the coherent coupling between laser light beams generated by adjacent unit light-emitting elements 4.

In the above manner, the semiconductor epitaxial growth layer 31 and the portion excluding the first contact layer 13 of one of the laminated structures K of the unit light-emitting elements 4 aligned in the array direction P are electrically insulated by the insulating layer 17. According to this configuration, the unit light-emitting elements 4 aligned in the array direction P can be optically coherently coupled while electrically connecting them in series.

In the above-described aspect, in the light-emitting element array 3, the unit light-emitting elements 4 are arrayed linearly or arrayed to have one or more bends. Also, the semiconductor epitaxial growth layer 31 is provided between the laminated structures K of the unit light-emitting elements 4 that are aligned in the crossing direction Q, which crosses the array direction P. According to this configuration, the semiconductor epitaxial growth layer 31 arranged between the laminated structures K of the unit light-emitting elements 4 aligned in the crossing direction Q can cause the laser light generated in one unit light-emitting element 4 to propagate to the adjacent unit light-emitting elements 4 in the crossing direction Q. Thereby, it is possible to further strengthen the coherent coupling between the laser light beams generated by the unit light-emitting elements 4 in the light-emitting element array 3, further improving the directivity and intensity of the laser light.

In the above-described aspect, the semiconductor epitaxial growth layer 31 and the laminated structure K of the unit light-emitting elements 4 aligned in the crossing direction Q are electrically insulated by the insulating layer 17. According to this configuration, the unit light-emitting elements 4 aligned in the crossing direction Q can be optically coherently coupled while electrically insulating each other.

1. A semiconductor light-emitting device including a plurality of unit light-emitting elements on a substrate,
wherein the unit light-emitting element has a laminated structure including an active layer and a photonic crystal layer, and first and second contact layers sandwiching the active layer and the photonic crystal layer, and
wherein a first contact layer of one unit light-emitting element and a second contact layer of another unit light-emitting element adjacent to the one unit light-emitting element are electrically connected by an electrode layer, whereby a plurality of light-emitting element arrays, each having a plurality of unit light-emitting elements arrayed in a row, are configured.

2. The semiconductor light-emitting device according to claim 1, wherein the plurality of light-emitting element arrays are electrically connected in parallel to each other.

3. The semiconductor light-emitting device according to claim 1, wherein the unit light-emitting elements are linearly arrayed in the light-emitting element array.

4. The semiconductor light-emitting device according to claim 1, wherein the unit light-emitting elements are arrayed to have one or more bends in the light-emitting element array.

5. The semiconductor light-emitting device according to claim 1, wherein, in one of the unit light-emitting elements,
the first contact layer forms an outermost layer on the substrate side in the laminated structure and has a projecting portion projecting toward the unit light-emitting element of a connection destination from the laminated structure in a plan view of the substrate,
the second contact layer forms an outermost layer opposite to the substrate in the laminated structure, and
the electrode layer electrically connects the projecting portion of the first contact layer and the second contact layer.

6. The semiconductor light-emitting device according to claim 5, wherein, in one of the unit light-emitting elements,
the first contact layer has an additional projecting portion projecting without extending toward the unit light-emitting element of the connection destination from the laminated structure in the plan view of the substrate, and
the electrode layer electrically connects the projecting portion and the additional projecting portion of the first contact layer to the second contact layer.

7. The semiconductor light-emitting device according to claim 6, wherein, in one of the unit light-emitting elements,
the laminated structure has a rectangular shape in the plan view of the substrate, and
the additional projecting portion projects outside of the laminated structure from one of a pair of edges along an array direction of the plurality of unit light-emitting elements in the plan view of the substrate.

8. The semiconductor light-emitting device according to claim 6, wherein, in one of the unit light-emitting elements,
the laminated structure has a rectangular shape in the plan view of the substrate, and
the additional projecting portion projects outside of the laminated structure from both edges of a pair along an array direction of the plurality of unit light-emitting elements in the plan view of the substrate.

9. The semiconductor light-emitting device according to claim 6, wherein, in one of the unit light-emitting elements,
the laminated structure has a rectangular shape in the plan view of the substrate, and
the additional projecting portion projects outside of the laminated structure from both edges of a pair along an array direction of the plurality of unit light-emitting elements in the plan view of the substrate and from a side opposite to the unit light-emitting element of the connection destination.

10. The semiconductor light-emitting device according to claim 1, wherein a region where the unit light-emitting elements are located is positioned at a central portion of the substrate, and a connection region between the light-emitting element arrays is positioned at an edge end portion of the substrate.

11. The semiconductor light-emitting device according to claim 1, wherein a semiconductor epitaxial growth layer is provided between the laminated structures of the unit light-emitting elements aligned in an array direction of the plurality of unit light-emitting elements, and
wherein the first contact layer of one of the unit light-emitting elements in the array direction is electrically connected to the second contact layer of the adjacent unit light-emitting element in the array direction by the semiconductor epitaxial growth layer and the electrode layer.

12. The semiconductor light-emitting device according to claim 11, wherein the semiconductor epitaxial growth layer is doped with the same polarity as the first contact layer.

13. The semiconductor light-emitting device according to claim 11, wherein the semiconductor epitaxial growth layer and a part other than the first contact layer of one of the laminated structures of the unit light-emitting elements aligned in the array direction are electrically insulated by an insulating layer.

14. The semiconductor light-emitting device according to claim 11, wherein, in the light-emitting element array, the unit light-emitting elements are arrayed linearly or arrayed to have one or more bends, and
wherein the semiconductor epitaxial growth layer is provided between the laminated structures of the unit light-emitting elements aligned in a crossing direction that crosses the array direction.

15. The semiconductor light-emitting device according to claim 14, wherein the semiconductor epitaxial growth layer and the laminated structure of the unit light-emitting elements aligned in the crossing direction are electrically insulated by an insulating layer.
